(19) United States
(12) Patent Application Publication
(10) Pub. No.: US 2009/0092467 A1
(43) Pub. Date: Apr. 9, 2009

(54) Stage apparatus

(76) Inventors: Yasuzou Tanaka, Kanagawa (JP); Junpei Yuyama, Kanagawa (JP); Mitsuru Yahagi, Kanagawa (JP); Hirofumi Minami, Kanagawa (JP)

Correspondence Address: Floyd B Carothers;Carothers And Carothers, 445 Fort Pitt Blvd Suite 500, Pittsburg, PA, 15219, US

(21) Appl. No.: 11/989,646

(22) PCT Filed: Feb. 23, 2007
(86) PCT No.: PCT/JP2007/053359

§ 371 Date: Jan. 29, 2008

(30) Foreign Application Priority Data
Mar. 6, 2006 (JP) 2006-059836

(51) Int. Cl. H01L 21/677

(52) U.S. Cl. 414/222.01; 414/222.04

(57) ABSTRACT

To enable division for transportation and secure proper treatment on a substrate to be treated, the present invention provides a stage apparatus (11) including a substrate holding plane which holds a substrate to be treated, a pair of guide frames (13X1), (13X2) oppositely disposed with the substrate holding plane sandwiched therebetween, and a gantry (13Y) which is movably held on upper surfaces of the pair of guide frames (13X1), (13X2). The stage apparatus (11) is composed of a first structure V1 which includes one guide frame (13X1), a second structure V2 which includes the other guide frame (13X2), and a third structure V3 which includes the gantry (13Y). Thus, even if the stage apparatus is large, since it can be divided into the structures V1 to V3, the stage apparatus can be transported by land. In addition, since there are no joints on a moving path of the gantry (13Y), the stage apparatus can properly treat the substrate without causing deterioration of moving accuracy.

### TECHNICAL FIELD

The present invention relates to a gantry moving type stage apparatus, in particular, to a stage apparatus used, for example, to coat various types of paste materials such as a sealing material, a liquid crystal material, and a spacer containing resin onto a glass substrate for a liquid crystal panel, or perform surface inspection or surface flatness measurement using a camera.

### RELATED ART

So far, for a coating step of coating various types of paste materials such as a sealing material, a liquid crystal material, and a spacer containing resin onto a glass substrate for a liquid crystal panel and a surface inspecting step using a camera, a gantry moving type stage apparatus has been used that moves a discharging nozzle that discharges a paste material or moves a camera in two directions of a plane of a glass substrate (for example, see the following patent document 1).

FIG. 4 is a plan view showing an outlined structure of a conventional stage apparatus of such a type. The shown conventional stage apparatus 1 has a substrate holding table 2 that holds a substrate to be treated on the XY plane, a pair of guide frames 3X, 3X that sandwich the substrate holding table 2 and extend in the direction of the X axis, a gantry 3Y that extends over the pair of guide frames 3X, 3X, and a substrate treatment unit 4 mounted on the gantry 3Y.

The gantry 3Y is mounted on the guide frames 3X, 3X such that the gantry 3Y can freely move on the upper surface of the guide frames 3X, 3X. The substrate treatment unit 4 is composed of, for example, a discharging nozzle that discharges various types of paste materials such as a sealing material, a liquid crystal material, and a spacer containing resin, or a camera unit that observes the front surface of the substrate. The substrate treatment unit 4 is mounted on the gantry 3Y such that the substrate treatment unit 4 can freely move on the lower surface of the gantry 3Y. The gantry 3Y and the substrate treatment unit 4 are moved along the guide frames 3X, 3X and the gantry 3Y, respectively, by a drive source such as a linear motor.

In the conventional stage apparatus 1 having the foregoing structure, the substrate treatment unit 4 is moved above the front surface of the substrate held on the substrate holding table 2. The substrate treatment unit 4, for example, coats the foregoing various types of paste materials onto the surface of the substrate or photographs the shape of the front surface of the substrate. By moving the substrate treatment unit 4 in the directions of the X axis and the Y axis, a predetermined treating operation of the substrate treatment unit 4 is intermittently or successively performed for the entire area of the substrate.

In a stage apparatus of this type, in addition to a work region R1 that defines a moving path of the gantry 3Y necessary to treat the substrate, each of the guide frames 3X has a non-work region R2 to which the gantry 3Y escapes from the overhead position of the substrate holding table 2, for example, so as to load and unload the substrate onto and from the substrate holding table 2 or maintain or inspect the substrate treatment unit 4. In other words, the guide frames 3X have a length of the work region R1 and the non-work region R2.

Patent Document 1: U.S. Pat. No. 3,701,882

Patent Document 2: Japanese Patent Application Laid-Open No. 2006-12911

### DISCLOSURE OF THE INVENTION

### Subject that the Invention is to Solve

In recent years, as the sizes of substrates to be treated have increased, the necessity of increasing the sizes of the stage apparatus that treat them has arisen.

However, as stage apparatus become large, it will become difficult to transport them. When the size of a substrate to be treated is, for example, 3000 mm×2800 mm, the shorter side of the stage apparatus necessarily becomes 3500 mm or more. Thus, the stage apparatus of this size cannot be transported by land according to the current road conditions.

To solve such a problem, a method of dividing a stage apparatus into a plurality of portions is known (for example, see the foregoing patent document 2). However, in the gantry moving type stage apparatus 1 shown in FIG. 4, if there are joints of the guide frames 3X on the moving path of the gantry 3Y, when the gantry 3Y passes through the joints, they will cause the gantry 3Y to vibrate and its moving speed to vary. As a result, the substrate treatment unit 4 may not be able to properly treat the substrate.

From the foregoing point of view, the present invention was made. An object of the present invention is to provide a stage apparatus that can be divided for land transportation and that can properly treat a substrate to be treated.

### Means for Solving the Problem

To solve the foregoing problem, a stage apparatus according to the present invention includes a substrate holding plane which holds a substrate to be treated, a pair of guide frames oppositely disposed with the substrate holding plane sandwiched therebetween, a gantry which extends over the pair of guide frames and which is movably held by the pair of guide frames, and a substrate treatment unit which is disposed on the gantry. The stage apparatus is composed of a first structure which includes one of the pair of guide frames, a second structure which includes the other of the pair of guide frames, and a third structure which includes the gantry.

In the stage apparatus having the foregoing structure according to the present invention, since the gantry and each of the guide frames that guide the gantry that moves are divided, the stage apparatus can be size-reduced such that it can be transported by land. In addition, since each of the guide frames is not divided, there are no joints on a moving path of the gantry. Thus, the gantry does not vibrate and its moving speed does not vary, resulting in allowing the stage apparatus to properly treat a substrate to be treated.

In addition, another stage apparatus of the present invention is a stage apparatus on which a substrate to be treated is mounted and a gantry is moved above the substrate so as to treat or inspect the substrate, including a pair of guide portions which movably support both leg portions of the gantry. The pair of guide portions are structured such that they are dividable for transportation.

The pair of guide portions correspond to, for example, linear guides that guide a linear movement of the gantry. When the pair of guide portions are mounted on the guide frames that can be freely divided, the foregoing operation and effect can be obtained.

### EFFECT OF THE INVENTION

As described above, according to the present invention, since the pair of guide frames that guide the gantry that moves or the guide portions are dividably structured, the stage apparatus can be size-reduced such that it can be transported by land. In addition, since the divide positions of the guide frames do not exist on the work region of the gantry, they do not cause the gantry to vibrate and its moving speed to vary, resulting in allowing the stage apparatus to properly treat a substrate to be treated.

### BRIEF DESCRIPTION OF DRAWINGS

FIG. 1 is a schematic diagram showing an outlined structure of a stage apparatus according to an embodiment of the present invention, in which A is an overall perspective view showing an assembled state of the stage apparatus and B is an overall perspective view showing a pre-assembled state of the stage apparatus.

FIG. 2 is a sectional view seen from the direction of the X axis of the stage apparatus according to the embodiment of the present invention.

FIG. 3 is a sectional perspective view showing an outlined structure of a movable portion of the stage apparatus according to the embodiment of the present invention.

FIG. 4 is a plan view showing an outlined structure of a conventional stage apparatus.

### DESCRIPTION OF REFERENCE NUMERALS

11 stage apparatus
12 substrate holding table
13X1, 13X2 guide frame
13Y gantry
14 substrate treatment unit
16, 16a, 16b pedestal
17 linear guide
17a guide shaft (first and second guide portions)
17b guide bearing
18 magnet
19 armature coil
20 movable portion
21 position detection sensor
22 linear scale

### BEST MODES FOR CARRYING OUT THE INVENTION

Next, with reference to the accompanying drawings, an embodiment of the present invention will be described. The present invention is not limited to the embodiment that follows. Various modifications may be made on the basis of the spirit of the present invention.

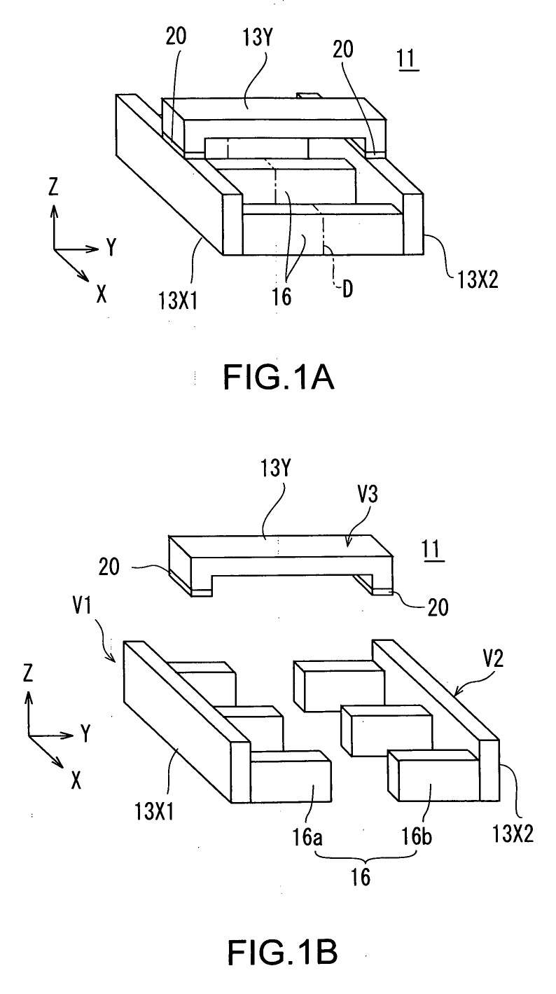

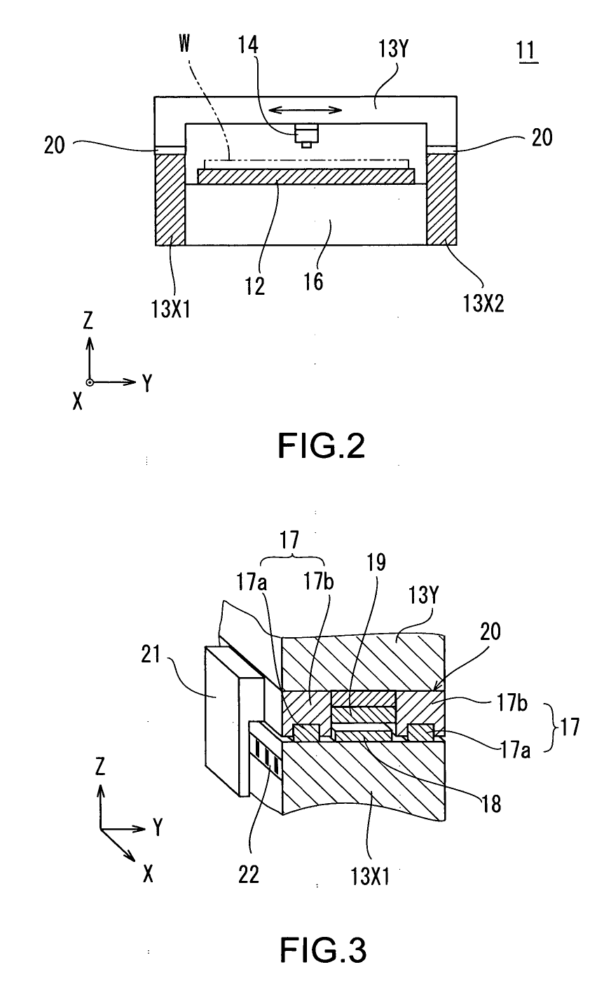

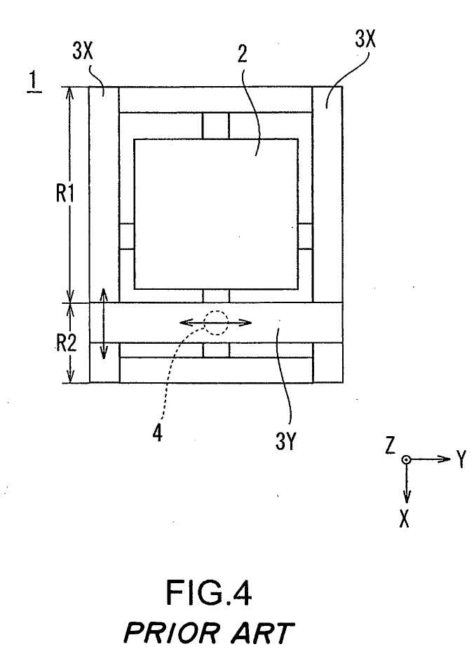

FIG. 1A and FIG. 1B are overall perspective views showing an outlined structure of a stage apparatus 11 according to an embodiment of the present invention, in which A shows an assembled state of the stage apparatus 11 and B shows a pre-assembled state of the stage apparatus 11. FIG. 2 is a sectional view seen from the direction of the X axis of the stage apparatus 11.

The stage apparatus 11 of this embodiment has a substrate holding table 12 that holds a substrate to be treated W such as a glass substrate, a pair of guide frames 13X1, 13X2 that sandwich the substrate holding table 12 and extend in the direction of the X axis, a gantry 13Y that extends over the pair of guide frames 13X1, 13X2, and a substrate treatment unit 14 that is mounted on the gantry 13Y.

The substrate holding table 12 has a substrate holding plane that holds the substrate to be treated W on the XY plane. The substrate holding table 12 is mounted on a pedestal 16 that causes the pair of guide frames 13X1, 13X2 to be oppositely disposed in parallel and spaced with a predetermined distance. The substrate holding table 12 has a mechanism that holds the substrate W on the substrate holding plane, for example, by vacuum suction. In FIG. 1A and FIG. 1B, the substrate holding table 12 is not shown. A part of the pedestal 16 may compose the substrate holding plane.

The pair of guide frames 13X1, 13X2 are integrally secured through the pedestal 16. The guide frames 13X1, 13X2 have a length of a moving path that defines a work region necessary for the gantry 13Y to perform a substrate treatment and a moving path that defines a non-work region to which the gantry 13Y escapes from the overhead position of the substrate to be treated W.

The gantry 13Y extends in a direction that intersects the direction in which the guide frames 13X1, 13X2 extend (the direction of the X axis). Specifically, in this embodiment, the gantry 13Y extends in a direction (the direction of the Y axis) perpendicular to the direction in which the guide frames 13X1, 13X2 extend. Both leg portions of the gantry 13Y are supported by the guide frames 13X1, 13X2 such that the leg portions are freely movable on the upper surface of the guide frames 13X1, 13X2 through a movable portion 20.

The substrate treatment unit 14 is composed of, for example, a discharging nozzle that discharges various types of paste materials such as a sealing material, a liquid crystal material, and a spacer containing resin to the front surface of the substrate W held on the substrate holding table 12, or a camera unit that observes the front surface of the substrate W. The substrate treatment unit 14 is held by the gantry 13Y such that the substrate treatment unit 14 is freely movable on the lower surface of the gantry 13Y.

The gantry 13Y and the substrate treatment unit 14 are moved along the guide frames 13X1, 13X2 and the gantry 13Y, respectively, by a linear motor as a drive source. FIG. 3 shows an example of a structure of the movable portion 20 disposed between the guide frame 13X1 and the gantry 13Y. The structure that follows is also applied between the guide frame 13X2 and the gantry 13Y and between the gantry 13Y and the substrate treatment unit 14.

As shown in FIG. 3, the movable portion 20 has a linear guide 17, a magnet 18, and an armature coil 19. The linear guide 17 is composed of a pair of guide shafts 17a, 17a mounted on the upper surface of the guide frame 13X1 and a pair of guide bearings 17b, 17b mounted on the lower surfaces of the leg portions of the gantry 13Y. The magnet 18 is linearly mounted on the upper surface of the guide frame 13X1 between the pair of guide shafts 17a, 17a. The armature coil 19 is mounted on the lower surfaces of the leg portions of the gantry 13Y such that the armature coil 19 faces the magnet 18 with a space. The magnet 18 and the armature coil 19 compose a linear motor.

Also mounted on the movable portion 20 is a position detection sensor 21 that detects a relative position of the gantry 13Y with respect to the guide frame 13X1. By optically detecting a linear scale 22 mounted on a side surface of the guide frame 13X1, the position detection sensor 21 detects the position of the gantry 13Y.

The stage apparatus 11 has a control section (not shown) that controls movements of the gantry 13Y and the substrate treatment unit 14 according to an output of the position detection sensor. The description of the control section will be omitted.

By horizontally moving the gantry 13Y in the direction of the X axis with respect to the guide frames 13X1, 13X2 and horizontally moving the substrate treatment unit 14 in the direction of the Y axis with respect to the gantry 13Y, the substrate treatment unit 14 can be positioned in two directions of the XY plane while facing the entire front surface of the substrate W held by the substrate holding table 12. As a result, the stage apparatus 11 is structured as an XY stage on which the substrate treatment unit 14 successively or intermittently performs a predetermined substrate treating operation (in this example, a coating treatment for a sealing material, a liquid crystal material, and a spacer containing resin, or a surface inspection) on the substrate to be treated W.

As shown in FIG. 1B, the stage apparatus 11 of this embodiment is composed of a first structure V1 that includes one guide frame 13X1, a second structure V2 that includes the other guide frame 13X2, and a third structure V3 that includes the gantry 13Y. Thus, the stage apparatus 11 can be freely divided into the guide frame 13X1, the guide frame 13X2, and the gantry 13Y.

The first structure V1 is composed of the guide frame 13X1, a part 16a of the pedestal 16, and so forth. The second structure V2 is composed of the guide frame 13X2, a part 16b of the pedestal 16, and so forth. The guide shafts 17a, the magnet 18, and so forth of the linear guide may be mounted on each of the guide frames 13X1, 13X2 in advance. The guide shafts 17a mounted on each of the guide frame 13X1 and the guide frame 13X2 correspond to “a pair of guide portions” of the present invention.

The third structure V3 is composed of the gantry 13Y, the substrate treatment unit 14, and so forth. Parts of the movable portion 20 may be mounted on the both leg portions of the gantry 13Y in advance. The substrate holding table 12 is detachable from the pedestal 16. After the guide frames 13X1, 13X2 are assembled, they are mounted on the pedestal 16.

As described above, according to this embodiment, since the guide frames 13X1, 13X2 are dividable in a direction perpendicular to a direction in which they extend, the frame portion of the stage apparatus 11 can be divided into two portions in the direction of the Y axis for transportation.

Even if the length in the direction of the X axis of the stage apparatus 11 is 5500 mm or more and the width in the direction of the Y axis thereof is 4500 mm or more, when the stage apparatus 1I is divided into two portions in the direction of the Y axis, the length of the shorter side of each divided structure can be limited to 3500 mm or less. Thus, since the restriction based on the road conditions is cleared, the stage apparatus 11 can be transported by land.

A boundary D (FIG. 1A) between one guide frame 13X1 side and the other guide frame 13X2 side is set nearly at the center portion in the direction of the Y axis of the pedestal 16 that connects these pair of guide frames 13X1, 13X2. As shown in FIG. 1B, the divided pedestals 16a and 16b are secured to the guide frame 13X1 and the guide frame 13X2, respectively. When the stage is assembled, end portions of the pedestals 16a and 16b are connected.

The position of the boundary D, namely the divide position of the pedestal 16, is not limited to the position of the foregoing example. The normal direction of the divided plane of the pedestal 16 is the direction of the Y axis. Instead, the normal direction of the divided plane may be a direction perpendicular to the direction of the Y axis. In addition, the guide frames 13X1, 13X2 may be diagonally divided.

In addition, since each of the guide frames 13X1, 13X2 itself is not dividably structured, there are no joints on the moving path of the gantry 13Y. Thus, the gantry 13Y does not vibrate and its moving speed does not vary. As a result, the stage apparatus can properly treat the substrate W. In addition, the gantry 13Y can be designed to have a desired moving accuracy. Thus, the guide frames 13X 1, 13X2 can be easily manufactured and installed.

The moving accuracy of the gantry 13Y includes the rigidity and flatness of the moving surface of the gantry 13Y, a uniform speed movement of the gantry 13Y, and so forth. To obtain these characteristics, the guide frames 13X1, 13X2 are made of a stone material such as granite or marble, or a material that has a relatively high machining accuracy such as a hard ceramic made of SiC.

Since the guide frames 13X1, 13X2 are not divided regarding the directions in which they extend, a linear guide (guide portion) and a linear scale can be mounted on the guide frames 13X1, 13X2. Thus, after the guide frames 13X1, 13X2 have been adjusted with respect to linear guide characteristics, the stage apparatus can be shipped. Thus, since the stage apparatus can be easily installed and adjusted at site, the working efficiency can be improved.

1. A stage apparatus, comprising:
a substrate holding plane which holds a substrate to be treaded;
a pair of guide frames oppositely disposed with the substrate holding plane sandwiched therebetween;
a gantry which extends over the pair of guide frames and which is movably held by the pair of guide frames; and
a substrate treatment unit which is disposed on the gantry,
wherein the stage apparatus is composed of:
a first structure which includes one of the pair of guide frames;
a second structure which includes the other of the pair of guide frames and is dividably connected to said first structure; and
a third structure which includes the gantry.

2. A stage apparatus on which a substrate to be treated is mounted and a gantry is moved above the substrate to treat or inspect the substrate, comprising:
a pair of guide portions which movably support spaced leg portions of the gantry,
wherein the pair of guide portions are structured such that they are dividable for transportation.
